(19) United States
(12) Patent Application Publication
(10) Pub. No.: US 2017/0051388 A1
(43) Pub. Date: Feb. 23, 2017

(54) Mask-Less Selective Plating of Leadframe

(71) Applicant: TEXAS INSTRUMENTS INCORPORATED, DALLAS, TX (US)

(72) Inventors: Donald C. Abbott, Norton, MA (US); Kapil H. Sahasrabudhe, Dallas, TX (US)

(21) Appl. No.: 15/346,688

(22) Filed: Nov. 8, 2016

Related U.S. Application Data
(62) Division of application No. 13/191,731, filed on Jul. 27, 2011.

(51) Int. Cl. C23C 8/04; C23C 8/02; H01L 21/48; C23C 8/52; C23C 18/16; C23C 8/72; C23C 8/12

(52) U.S. Cl. CPC C23C 8/04; C23C 8/72; C23C 8/02; C23C 8/12; C23C 8/52; C23C 18/1633; H01L 21/4821

(57) ABSTRACT

A method for selectively plating a leadframe (1100) by oxidizing selected areas (401, 402, 403, 404) of the leadframe made of a first metal (102) and then depositing a layer (901) of a second metal onto un-oxidized areas. The selective oxidations are achieved by selective active marking

### CROSS-REFERENCE TO RELATED APPLICATION

This divisional application claims priority to and the benefit of U.S. patent application Ser. No. 13/191,731 (TI-68593), filed on Jul. 27, 2011, the entirety of which is incorporated herein by reference.

### FIELD OF THE INVENTION

The present invention is related in general to the field of semiconductor devices and processes, and more specifically to the structure and fabrication process of metallic leadframes in semiconductor packages having low-cost mask-less selective plating, while oxidizing the un-plated leadframe portions to provide improved adhesion to the polymeric compounds.

### DESCRIPTION OF RELATED ART

In semiconductor devices, the chips are encapsulated in packages to protect the enclosed parts against mechanical damage and environmental influences, particularly against moisture and light, while providing trouble-free electrical connections. Based on their functions, the semiconductor packages include a variety of different materials; metals are employed for electrical and thermal conductance, and insulators, such as polymeric molding compounds, are used for encapsulations and form factors. To ensure the unity and coherence of the package, these different materials are expected to adhere to each other during the lifetime of the package while tolerating mechanical vibrations, temperature swings, and moisture variations. Failing adhesion allows moisture ingress into the package, causing device failure by electrical leakage and chemical corrosion.

Leadframes for semiconductor devices provide a stable support pad for firmly positioning the semiconductor chip, usually an integrated circuit (IC) chip, within a package. The chips have to be attached to the pad with reliable adhesion. It has been common practice to manufacture single piece leadframes from thin (about 120 to 250 μm) sheets of metal. For reasons of easy manufacturing, the commonly selected starting metals are copper, copper alloys, iron-nickel alloys (for instance the so-called “Alloy 42”), and aluminum. The desired shape of the leadframe is stamped or etched from the original sheet.

In addition to the chip pad, the leadframe offers a plurality of conductive leads to bring various electrical conductors into close proximity of the chip. The remaining gaps between the inner end of the leads and the contact pads on the IC surface are bridged by connectors, typically thin metal wires of gold or copper, individually bonded to the IC contact pads and the leads. Consequently, the surface of the inner lead ends has to be metallurgically suitable for Mitch-attaching the connectors.

The end of the leads remote from the IC chip (“outer” ends) need to be electrically and mechanically connected to external circuitry such as printed circuit boards. This attachment is customarily performed by soldering, conventionally with a tin alloy solder at a reflow temperature above 200° C. Consequently, the surface of the outer lead ends needs to have a metallurgical configuration suitable for reflow attachment to external parts.

Finally, the leadframe provides the framework for encapsulating the sensitive chip and fragile connecting wires. Encapsulation using plastic materials, rather than metal cans or ceramic, has been the preferred method due to low cost. The transfer molding process for epoxy-based thermoset compounds at 175° C. has been practiced for many years. The temperature of 175° C. for molding and mold curing (polymerization) is compatible with the temperature of >200° C. for eutectic solder reflow. The encapsulation compound has to adhere reliably to leadframe, chip and wires.

Today's semiconductor technology employs a number of methods to raise the level of adhesion between the diversified materials so that the package passes accelerated tests and use conditions without delamination. As an example, the adhesion between copper-based leadframes and epoxy based molding compounds and chip-attach compounds can be improved by adding design features such as indentations, grooves or protrusions to the leadframe surface. A widely used technique is the mechanical “dimpling” of the underside of the chip attach pad by producing patterns of indentations in the leadframe metal, sized between about 500 and 1000 μm. Another example to improve adhesion is the method to chemically modify the leadframe surface by oxidizing the metal surface, for instance creating copper oxide. Copper oxide is known to adhere well to epoxy-based molding compounds.

Another example of known technology to increase adhesion between leadframe, chip, and encapsulation compound in semiconductor packages, is the roughening of the whole leadframe surface by chemically etching the leadframe surface after stamping or etching the pattern from a metal sheet. Chemical etching is a subtractive process using an etchant. When, for some device types, the roughening of the metal has to be selective, protective masks have to be applied to restrict the chemical roughening to the selected leadframe areas; the application of masks is material-intensive and thus expensive. Chemical etching creates a micro-crystalline metal surface with a roughness on the order of 1 μm or less.

Yet another known method to achieve a rough surface is the use of a specialized nickel plating bath to deposit a rough nickel layer. This method is an additive process; it has to employ a protective photomask when the deposition has to be restricted to selected leadframe portions. The created surface roughness is on the order of 1 to 10 μm.

### SUMMARY OF THE INVENTION

Applicant recognized that two major contributors to good adhesion are the chemical affinity between the molding compound and the metal finish of the leadframe, and the surface roughness of the leadframe. In recent years, a number of technical trends have made it more and more complicated to find a satisfactory solution for the diverse requirements, First of all, package dimensions are shrinking, offering less surface area for adhesion. Then, the requirement to use lead-free solders pushes the reflow temperature range into the neighborhood of about 260° C., making it more difficult to maintain mold compound adhesion to the leadframes. This is especially true for the very small leadframe surface available in QFN (Quad Flat No-lead) and SON (Small Outline No-lead) devices.

Applicant further recognized that it is counterproductive when contemporary leadframes have metal layers plated for enhanced wire bonding or solderabililty and use flood plating as a low cost plating method, resulting in plated metals in areas which are superfluous for bonding or soldering but rather should be utilized for enhancing adhesion. Improved definition of leadframe functions calls for selective metal layer plating. Applicant saw that for selective plating, traditional masks which just protect and are otherwise inactive, are not practical because reusable rubber masks are not suitable for slow plating processes or precision multilayer plating, and photoimagible resist masks are too expensive, especially for multilayer plating.

Applicant solved the problem of moisture-induced device failures caused by insufficient adhesion by introducing the concept of selective active marking. The marker, in contact with selected areas of a first metal, actively oxidizes the areas so that a layer of a second metal, deposited by a subsequent plating step, will barely adhere and can thus be peeled away easily; the second metal may not even deposit in the first place. As a result, the first metal of the leadframe is plated only in un-marked areas with a layer of a second metal, while the un-plated oxidized areas are greatly improved for adhering to polymeric compounds.

In one method, the leadframe is contacted with a rubber stamp patterned by mesas, which have been dipped in a strongly oxidizing chemical agent such as sodium hypochlorite (NaOCl), which can be easily cleaned away. Alternatively, any suitable bleach may be used.

In an alternative method, applicant used an apparatus of heated probes to locally contact and oxidize the leadframe. The apparatus carrying the probes, patterned to match the leadframe areas to be oxidized, may include electrically heated probes, where the time needed for locally reaching elevated temperatures is short; the spreading of thermal energy into adjacent leadframe regions is thus short, causing only minor oxidation, which can be removed by acid treatment before dipping the leadframe into the plating station.

The preferred plating method is the low-cost flood plating. The areas of plated metal may have diffuse or uneven edges, which, however, do not affect functionality. Any traces of second metal loosely deposited on the oxidized areas are easily peeled off.

It is a technical advantage that the methods of the invention can be applied even to the fine geometries QFN/SON-type leadframes (Quad Flat No-Lead, Small Outline No-Lead). It is another advantage that the methods are low-cost and the employed tools can be re-used.

The first metal may be copper or a copper alloy; alternatively, the first metal may be aluminum, an iron-nickel ahoy (such as Alloy 42), or Kovar™. The second metal may be nickel; alternatively, the second metal may include a layer of nickel in contact with the first metal, a layer of palladium in contact with the nickel, and a layer of gold in contact with the palladium.

### BRIEF DESCRIPTION OF THE DRAWINGS

FIG. 1 depicts a schematic top view of a leadframe after forming it from a starting sheet of a first metal.

FIG. 2 is a schematic cross section of the formed leadframe of FIG. 1.

FIG. 3 illustrates a schematic cross section of a first apparatus, suitable for oxidizing selected areas of the leadframe, applied to the leadframe of FIG. 2.

FIG. 4 shows a schematic cross section of the leadframe of FIG. 3 after removing the first apparatus used for the oxidation step.

FIG. 5 shows a schematic cross section of a second apparatus, suitable for oxidizing selected areas of the leadframe, applied to the leadframe of FIGS. 2.

FIG. 6 shows a schematic cross section of the leadframe of FIG. 5 after removing the second apparatus used for the oxidation step.

FIG. 7 depicts a schematic top view of the leadframes of FIG. 4 and FIG. 6 after the oxidation step illustrated in FIG. 3 and FIG. 5.

FIG. 8 illustrates a schematic top view of the leadframe of FIG. 7 after plating a second metal over the whole leadframe.

FIG. 9 shows a schematic cross section of the leadframe of FIG. 4 after plating a second metal over the whole leadframe.

FIG. 10 shows a schematic cross section of the leadframe of FIG. 6 after plating a second metal over the whole leadframe.

FIG. 11 illustrates a schematic top view of the leadframe of FIG. 8 after removing the second metal layers plated over the oxidized leadframe portions.

FIG. 12 depicts a schematic cross section of the leadframe of FIG. 9 after removing the second metal layers plated over the oxidized leadframe portions.

FIG. 13 depicts a schematic cross section of the leadframe of FIG. 10 after removing the second metal layers plated over the oxidized leadframe portions.

### DETAILED DESCRIPTION OF THE PREFERRED EMBODIMENTS

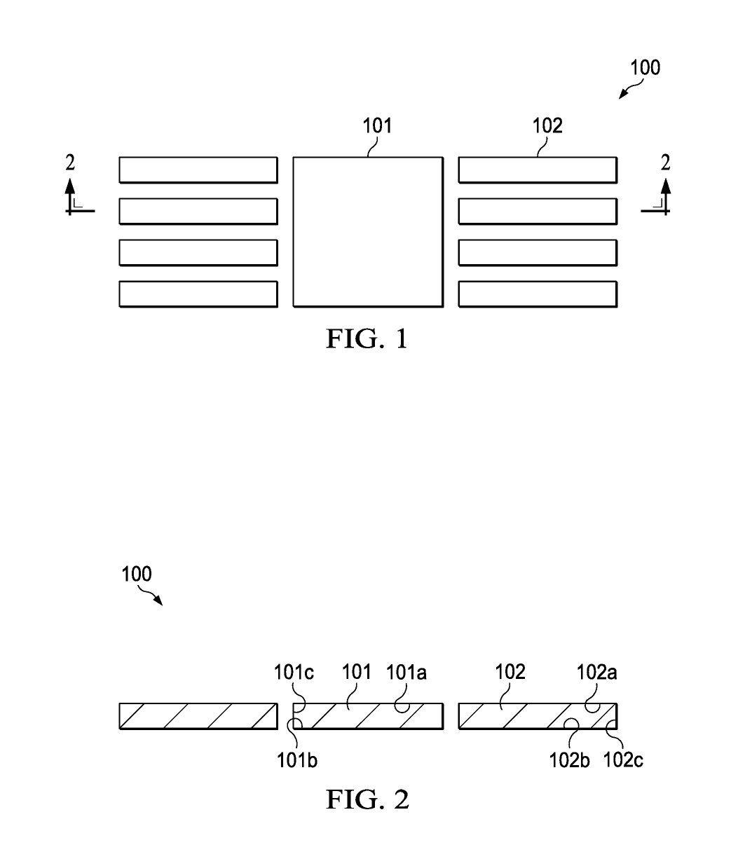

FIG. 1 illustrates schematically the top view of a metal leadframe, generally designated 100, as used in a wide variety of semiconductor devices, and FIG. 2 is a cross section of the leadframe along the line indicated in FIG. 1. Not shown in FIGS. 1 and 2 are frame and tie bars of the leadframe. Leadframe 100 is made of a first metal selected from a group including copper, copper alloy, aluminum, iron-nickel alloy, and Kovar™. The leadframe originates with a sheet of the first metal in the preferred thickness range from 100 to 300 μm; thinner or thicker sheets are possible. The pattern of the leadframe is stamped or etched from the starting sheet; it includes a pad 101 for attaching a semiconductor chip and a plurality 102 of leads.

FIG. 2 displays a cross section of the leadframe including pad 101 and leads 102. As FIG. 2 indicates, all leadframe features have a plurality of surfaces. For example, pad 101 has a first surface 101a and an opposite second surface 101b. It should be noted that herein first surface 101a is referred to as the top surface since it serves as the attachment surface for a semiconductor chip, and second surface 102 is referred to as the bottom surface. Further, pad 101 has a plurality of side surfaces 101c. In analogous fashion, lead 102 has a top surface 102a, a bottom surface 102b, and a plurality of side surfaces 102c. These surfaces have to support a number of functions essential for successful assembly, packaging, and operation of the semiconductor device; examples of such functions include attaching a chip, welding wire stitches, adhering to polymeric compounds, and soldering to external parts. To enable these functions reliably, the respective leadframe portions have to be given appropriate surface constitutions. For example, reliable adhesion to adhesive and molding compounds requires leadframe surfaces with affinity to polymeric formulations; on the other hand, reliable soldering requires leadframe surfaces, which can be wetted. The leadframe zones of different constitutions are often located side by side, or are restricted to selected areas.

As an example, in FIG. 2 surface 101a may have to be prepared for attaching a semiconductor chip, surfaces 101b and 101c for adhering to a molding compound. Even more complicated, a portion of surfaces 102a may have to be prepared for stitch-welding a bonding wire, another portion for adhering to a molding compound, and yet another portion for wetting by a solder. The surfaces 102c nearest pad 101 may have to be prepared for adhesion to molding compounds, and surfaces 102c remote from pad 101 for wetting by solder.

Among the popular methods to achieve surface constitutions for reliable welding and soldering are the plating techniques for depositing metal layers. However, when a plating technique involves the use of masks, the ongoing trend to miniaturize semiconductor devices and scale leadframes makes masking expensive, especially when photomasks and alignments are employed. Repeated mask applications, often required for consecutive plating baths, are uneconomical. An example are the consecutive depositions of a nickel layer on the first metal, followed by a palladium layer on the nickel layer, followed by a gold layer on the palladium layer.

Adhesion is the tendency due to intermolecular forces for matter to cling to other matter. Among successful metal surface constitutions for reliable adhesion to polymeric compounds are metal oxides. Incidental exposure to ambient and operations, such as clean-ups under environmental conditions, allows the interaction of oxygen with surface-near metal atoms to form oxides, creating thin and usually incomplete metal-oxide films. The readiness for oxide-formation (release of electrons) increases with the electronegative potential of the metal; for example, aluminum has an electrochemical potential of −1.66 V (relative to a hydrogen electrode), nickel—0.25 V, copper of +0.34 V, gold +1.5 V. The more electronegative an element is, the stronger is its reducing force, or the easier it can be oxidized.

In contrast to the observation that polymeric compounds adhere well to metal oxides is the fact that it is difficult to make a deposited layer of a second metal stick to an oxidized first metal. After a layer of a second metal is deposited on an oxidized first metal substrate, it is mechanically easy to peel or scratch it off due to its lack of adherence to the oxidized first metal. As stated, the second metal is chosen to promote welding of wire stitch bonds and soldering to external parts.

Based on these facts, applicant reversed the conventional way of selective plating. Rather than using masks to selectively deposit a second metal layer on a first metal substrate, the new method uses simple tools to selectively oxidize the first metal. A layer of second metal is then deposited by a low-cost flood plating technique, and followed by a peeling of those layer portions, which do not adhere to the oxidized first metal areas. The result is a substrate made of a first metal, which exhibits a second metal layer in certain areas for promoting stitch bonding and solder attaching, and further exhibits intentionally oxidized surfaces for promoting adhesion to polymeric compounds.

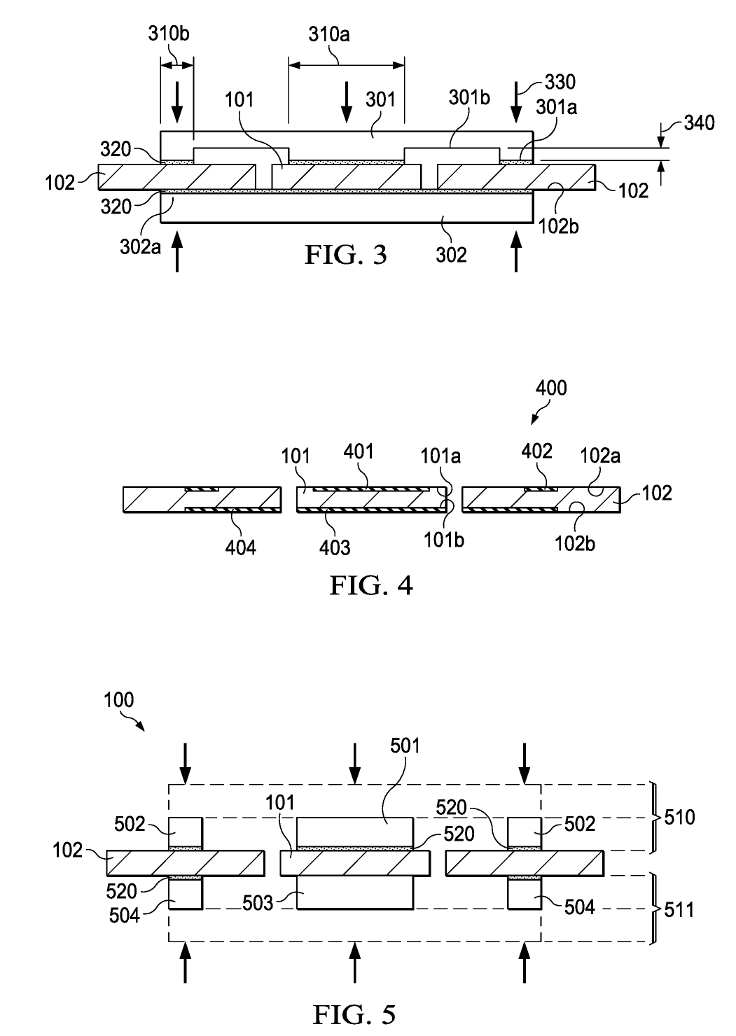

FIGS. 3 and 5 illustrate schematically two exemplary methods and tools for selectively oxidizing a leadframe. The method used in FIG. 3 is based on a tool functioning as a stamp, which transfers a strongly oxidizing agent and presses it against leadframe portions. The method used in FIG. 5 is based on a tool functioning as a sort of branding iron, which can be heated locally and transfers thermal energy to leadframe portions for accelerating oxidation of leadframe metal.

Shown in FIG. 3 are pad 101 and leads 102 of an exemplary leadframe, clamped by a top portion 301 and a bottom portion 302 of an exemplary stamp. The stamp may be made of rubber or any other material suitable to be patterned in the design of the leadframe areas to be oxidized and chemically inert enough for transporting a strongly oxidizing agent such as sodium hypochlorite (NaOCl). In FIG. 3, top portion 301 displays sections with the original surface 301a and other sections with a recessed surface 301b, The height difference between surface 301a and surface 301b represents the height 340 of a mesa; preferably, height 340 is the same for all mesas. The mesas may have different width; FIG. 3 depicts width 310a for the mesa intended to create an oxidized area for leadframe pad 101 suitable to attach a semiconductor chip; and width 310b for leads 102 intended to create oxidized areas of the leads suitable to enhance adhesion to encapsulation compounds. In FIG. 3, width 310b is the same for all mesas intended for leads 102, but in other devices, the width 310b may be different for different leads. The pattern of stamp portion 301 can thus be customized in accordance with specific leadframe leads. Mesas 310a and 310b transport the oxidizing agent 320. In FIG. 3, bottom portion 302 is shown with a uniform original surface 302a, since in is not used with any pattern in this example. Consequently, the uniform surface 302a transports the oxidizing agent 320. It should be stressed, however, that the patterning of top portion 301 and bottom portion 302 can be changed at liberty from device to device as required by the need of creating oxidized areas of the leadframe. As an example, no agent 320 at all may be applied to surface 302a so that there will be no oxide formed of the first metal surface 102b.

The arrows 330 in FIG. 3 indicate that at the start of the process the stamp portions 301 and 302 do not yet touch the leadframe; rather, they are dipped into an agent 320, or they otherwise acquire the agent onto their surfaces (for instance by brushing against it). Thereafter, the stamp portions are aligned with the leadframe and moved along arrows 330 to touch the leadframe's first metal for instance, copper) surfaces. By pressing stamp portions 301 and 302 against the leadframe metal, the oxidizing agent becomes active to oxidize the touched first metal (the result is shown in FIG. 5). When sodium hypochlorite is the oxidizing agent, NaOCl gives off its oxygen to form the desired metal oxide (for instance, copper oxide), while salt (NaCl) is left over. Experience has shown that the edges of the oxidized first metal areas, bordering the not-oxidized metal area, are somewhat diffuse.

The result of the leadframe oxidation step using the stamp in FIG. 3 is depicted in FIG. 4. The leadframe, in its oxidized status generally designated 400, shows on its top surfaces 101a and 102a the oxidized surface layers as imprints of the stamp mesas: Oxide layer 401 on the leadframe pad reflects the extent of the mesa dimension 310a, and oxide layers 402 on the leads 102 reflect the extent of the mesa dimensions 310b. On its bottom surfaces 101a and 101b, leadframe 400 shows the oxidized surface layers as imprints of surface 302a of the large stamp portion 302; consequently, the oxide layers stretch across the leadframe pad 101 (oxide layer 403) and portions of the leads 102 (oxide layers 404).

It should be noted that other techniques, related to but different from stamping, can produce similar oxidation results. As an example, one such technique uses the movable jet of an oxidizing liquid (technique related to ink jet).

FIG. 5 illustrates a tool for another method to selectively oxidize leadframe surfaces. The method is based on the fact that metal oxidation by oxygen of the ambient can be rapidly accelerated when the temperature of the metal-to-be-oxidized is increased. To exploit this fact, the exemplary tool of FIG. 5 is based on probes, which can be individually heated, for instance by electrical current.

The exemplary tool of FIG. 5 has a top half 510 and a bottom half 511. The top half 510 has elongated probes of two distinct widths 501 and 502, which can be heated. In the example of FIG. 5, top half 510 with probes 501 and 502 is designed so that the probes will create leadframe oxide areas of sized to match the oxide areas produced by the top half 301 of the stamp tool described in FIG. 3. The shaded cross sections 520 of the probe tips schematically indicate the volumes of high temperature of the probes. Probe 501 is selected to oxidize a pad area suitable to attach a semiconductor chip (in the example of FIG. 5 the same area as created by mesa diameter 310a in FIG. 3).

The bottom tool half 511 also has probes, which may be elongated and heatable. In the example of FIG. 5, the bottom half includes an elongated probe 503 of a width similar to the width of probe 501, and a plurality of probes 504 of a width similar to the width of probes 502. Again, the shaded cross sections 520 of the probe tips schematically indicate the volumes of high temperature of the probes. In order to emphasize the flexibility of choices, probe 503 is illustrated as not heatable, while probes 504 are heatable. It should be pointed out that the probe widths may be customized to oxidize any metal area desired.

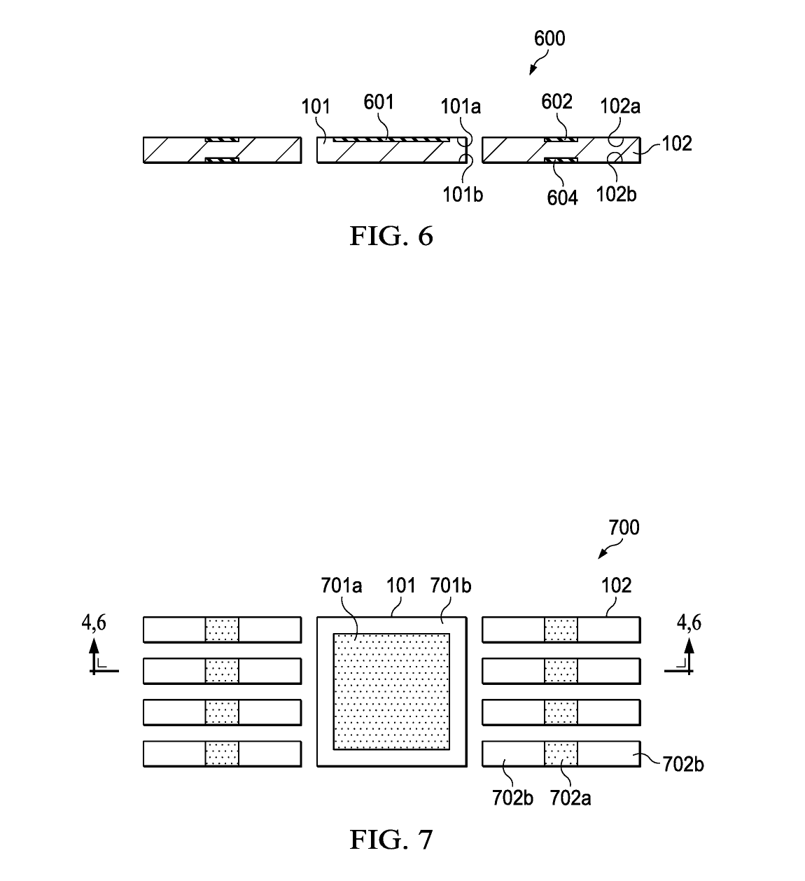

The result of the leadframe oxidation step using the stamp in FIG. 5 is depicted in FIG. 6. The leadframe, in its oxidized status generally designated 600, shows on its top surfaces 101a and 102a the oxidized surface layers as imprints of the heated probes: Oxide layer 601 on the leadframe pad reflects the extent of the dimension of probe 501, and oxide layers 602 on the leads 102 reflect the extent of the dimensions of probes 502. On its bottom surfaces 101a and 101b, leadframe 600 shows the oxidized surface layers as imprints only of the surfaces of probes 504, since in this example probe 503 is not heatable; consequently, only leads 102 will receive oxide layers 604.

It should be noted that other heating techniques can produce similar oxidation results. As an example, one such technique employs movable focused laser beams.

FIG. 7 displays the top surface of an exemplary leadframe generally designated 700 after selectively oxidizing first metal areas so that a semiconductor chip can be attached and wire-bonded. Oxidized areas are marked by a first kind shading in FIG. 7. As stated above, the exemplary oxidation tools described in FIGS. 3 and 5 had the capability to create identical oxide areas on the top leadframe surface, as illustrated in the cross sections of FIGS, 4 and 6 and referred to by the cutaway line marked 4,6 in FIG. 7. Consequently, the identical result of those oxidation techniques is displayed in FIG. 7. Chip attach pad 101 includes the metal-oxide area 701a for attaching the semiconductor chip, surrounded by un-oxidized frame 701b intended for affixing a chip down-bond wire. The surface of frame 701b displays the unchanged first metal shown in FIG. 1. Metal-oxide 701a of FIG. 7 has been shown to greatly improve the adhesion between epoxy-based chip attach compounds and the leadframe pad 101. For other semiconductor devices, which do not require wire down-bonds, it is preferred to extend the oxidized area 701a across the whole chip pad area 101, thus incorporating the metallic frame area 701b in the oxidized pad portion.

Of the plurality of leads 102, each lead has an oxidized area 702a and left-over un-oxidized portions 702b displaying the first metal of the leadframe. Due to their selectively oxidized areas 702a, leads 102 offer greatly enhanced adhesion for polymeric encapsulation compounds.

After the selective oxidation step of the invention, it is advisable to clean the leadframe in a so-called reduction step. By this quick-time clean-up step, any thin, unintentional, or accidental oxide film can be removed from metal surfaces, which have not been oxidized by the selective techniques described above. Metal surface designated 701b and 702b in FIG. 7 will thus be clean and ready for the deposition step of a second metal described in FIG. 8.

Subsequent to the selective oxidation step of the invention, a layer of a second metal is deposited on leadframe. The preferred deposition method is a low-cost plating technique such as flood plating. Alternatively, other deposition methods such as sputtering or evaporation may be used. The deposited second metal adheres well to the un-oxidized areas, but only poorly or not at all to the oxidized areas. The resulting leadframe is shown in FIG. 8 and generally designated 800; the deposited second metal is generally indicated by a second kind shading. Since the whole leadframe has been subjected to the deposition of the second metal, the second kind shading covers all parts of the leadframe in the top view of FIG. 8. The fact that the second metal is deposited as a layer becomes evident by cutaways along the line marked 9,10 in FIG. 8.

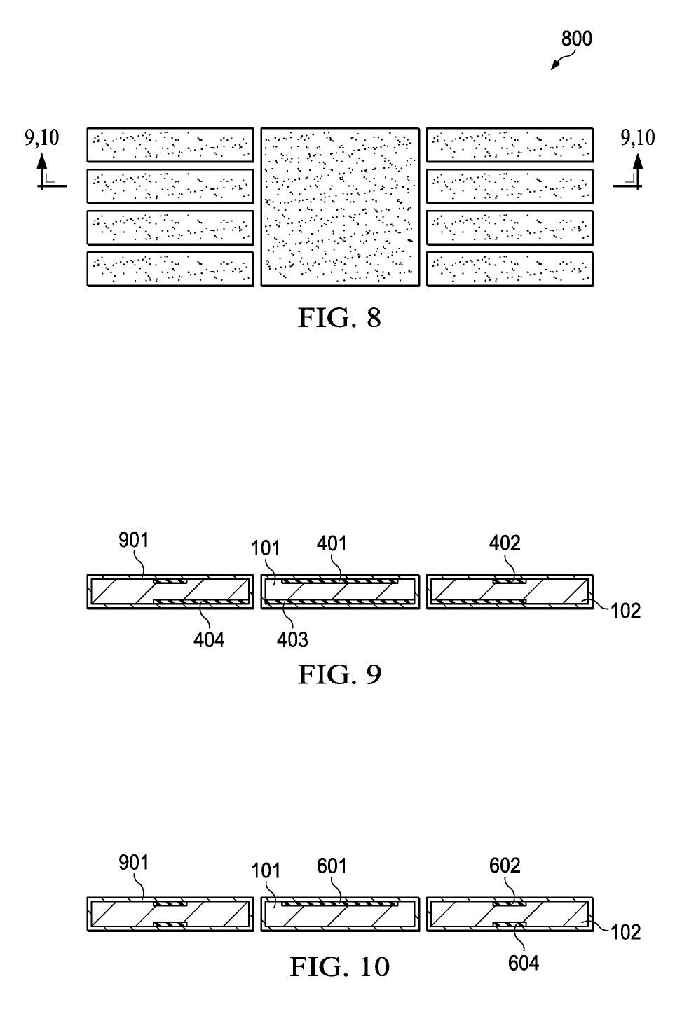

If the leadframe had been selectively oxidized by the stamp technique of FIG. 3, whereby the oxidized areas were formed in a distribution as shown in the cross section of FIG. 4, the cutaway line in FIG. 8 through the plated leadframe produces a cross section of the plated leadframe as illustrated in FIG. 9. If the leadframe had been selectively oxidized by the probe technique of FIG. 5, whereby the oxidized areas were formed in a distribution as shown in the cross section of FIG. 6, the cutaway line in FIG. 8 through the plated leadframe produces a cross section of the plated leadframe as illustrated in FIG. 10. In both FIGS. 9 and 10, the second metal is deposited as layer 901 on all surfaces of the pad 101 and the leads 102. Layer 901 is uniform in all leadframe areas where the second metal is deposited on the first metal; the second metal layer also adheres strongly to the first metal. However, where FIGS. 9 and 10 show layer 901 over oxidized areas (401, 402, 403, 404, 601, 602, 604), the second metal is not adhering to the first metal. For some deposition techniques and for some metals, layer 901 may be much thinner over oxidized areas than over first metal areas, or layer 901 may have been unable to stick to oxidized surfaces, leaving the oxidized areas devoid of second metal and looking un-covered and open.

As an example for leadframes with copper as first metal a frequently used plating step includes nickel as second metal; the thickness of layer 901 may vary from submicron to several μm. It is a technical advantage of the invention to provide a patterned layer of the relatively slowly deposited nickel without the help of re-usable rubber masks, which are known to be cumbersome for metals with slow plating rates.

Another frequently employed second metal includes a nickel layer in the thickness range from about 0.5 to 2.0 μm in contact with the first metal copper, followed by a palladium layer in the thickness range from about 0.01 to 0.1 μm in contact with the nickel layer, followed by a gold layer in the thickness range from about 0.003 to 0.009 μm in contact with the palladium layer. It is a technical advantage of the selective oxidation approach that these stacks of metal layers can be deposited, and are inherently precisely aligned, without photomasks and without alignment; the sequence of layers can be deposited just by moving from one plating bath to the next. In contrast, it is known that conventional selective plating of multilayer structures (NiPd, NiAu, NiPdAu, etc.), which include nickel, is time consuming and costly because of the need for photoimagible plating resist.

Yet another example of second metal is in; the thickness of layer 901 may vary over a wide range.

The fact that any second metal deposited on selectively oxidized first metal areas adheres poorly or not at all to the surface of the oxidized first metal, allows an easy process step of removing any such deposited second metal from those oxidized areas. For example, any second metal layer 901 plated on oxidized areas can peeled by mechanical means from the oxidized metal Preferred methods include removing by air knife, water jet, bead blast, and tape. It has been found that peeling can be promoted by briefly heating the leadframe after the plating step. Further, it has been found that the thickness of the metal oxide layer can be optimized so that in the plating process, no or extremely low deposition occurs on the oxidized metal surface. This phenomenon makes an additional step of removing any plated second metal superfluous.

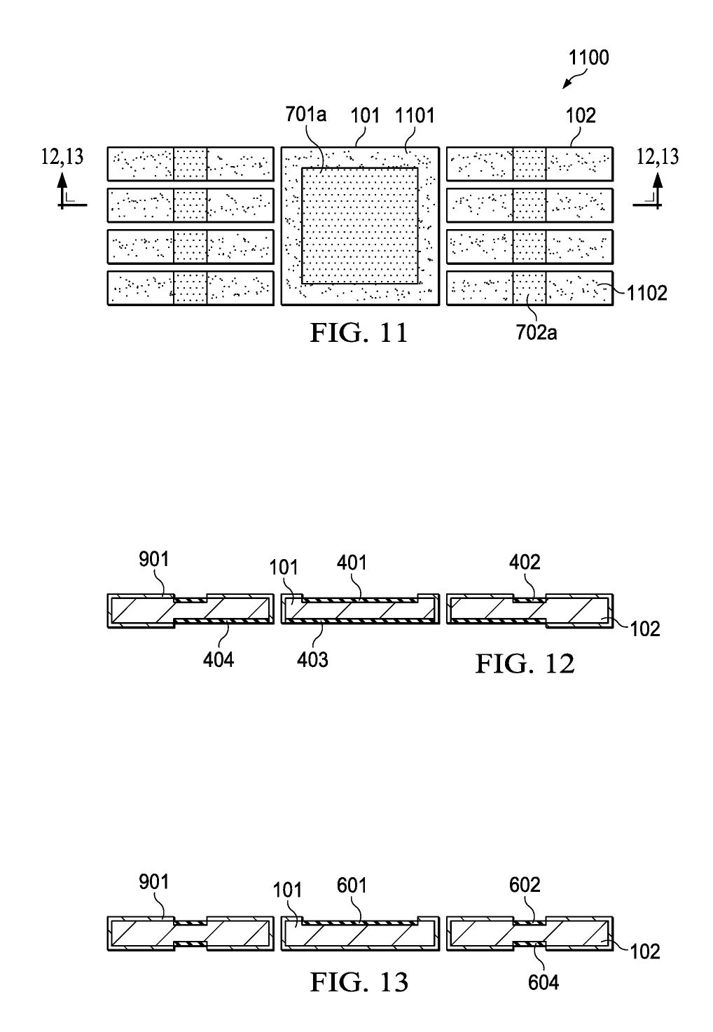

FIG. 11 displays the top surface of an exemplary finished leadframe of a first metal after selective oxidation of first metal areas and subsequent deposition of a second metal on the un-oxidized first metal areas. The leadframe, generally designated 1100, has the oxidized areas marked by a first kind shading (like in FIG. 7) and the areas with a second metal layer by a second kind shading (like in FIG. 8). Since any second metal deposited in oxidized areas has been removed by a peeling process as described above, the oxidized areas are clearly exposed and visible. Chip attach pad 101 includes the metal-oxide area 701a for attaching the semiconductor chip, surrounded by frame 1101 covered by second metal and intended for affixing a chip down-bond wire. Metal-oxide 701a of FIG. 11 has been shown to greatly improve the adhesion between epoxy-based chip attach compounds and the leadframe pad 101. For other semiconductor devices, which do not require wire down-bonds, it is preferred to extend the oxidized area 701a across the whole chip pad area 101 and eliminate metal frame 1101a.

Of the plurality of leads 102, each lead has an oxidized area 702a and portions 1102 displaying the deposited second metal Due to their selectively oxidized areas 702a, leads 102 offer greatly enhanced adhesion for polymeric encapsulation compounds, and due to their deposited second metal 1102, leads 102 offer greatly enhanced bondability for wire bonds and metal bumps, and solderability for solder attachment.

The cutaway line marked 12,13 in FIG. 11 indicates the cross sections of FIGS. 12 and 13 of the finished leadframe. If the leadframe had been selectively oxidized by the stamp technique of FIG. 3, whereby the oxidized areas were formed in a distribution as shown in the cross section of FIG. 4, the cutaway line in FIG. 11 through the plated and cleaned leadframe produces a cross section of the plated leadframe as illustrated in FIG. 12. If the leadframe had been selectively oxidized by the probe technique of FIG. 5, whereby the oxidized areas were formed in a distribution as shown in the cross section of FIG. 6, the cutaway line in FIG. 11 through the plated and cleaned leadframe produces a cross section of the plated leadframe as illustrated in FIG. 13. In both FIGS. 12 and 13, the second metal is deposited as layer 901 on all surfaces of the pad 101 and the leads 102, but has been removed and cleaned from all oxidized first metal areas: Chip attach pads 401 and 601; encapsulation adhesion areas 402, 403, 404, 602, and 604. Layer 901 is uniform in all leadframe areas where the second metal is deposited on the first metal; the second metal layer also adheres strongly to the first metal. As mentioned above, the deposited second metal layers have diffuse edges bordering the oxidized areas (in contrast to sharply defined edges in devices employing photomasks).

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing.

As another example, the invention applies to all leadframe-based semiconductor packages.

As another example, the oxidation process steps described can be combined with other techniques to improve adhesion such as surface roughening, forming dimples and other features for enhanced grasping, and partial etching, including so-called half-etched leadframes.

It is therefore intended that the appended claims encompass any such modifications or embodiment.

I claim:

1. A method for selectively plating a leadframe comprising:
using a maskless process to selectively oxidize a plurality of selected areas of a leadframe made of a first metal leaving a plurality of un-oxized areas; and
depositing a layer of a second metal onto the plurality un-oxidized areas;
wherein the step of selectively oxidizing includes the step of transferring heat into the selected leadframe areas for accelerating oxidation of the first metal.

2. The method of claim 1 wherein the second metal layers have diffuse edges bordering the plurality of selected oxidized areas.

3. The method of claim 1 wherein the step of transferring heat includes a tool having elongated probes matching the selected leadframe areas, the probes suitable to be electrically heated.

4. The method of claim 1 wherein the step of transferring heat includes a movable laser beam.

5. The method of claim 1 wherein the first metal is selected from a group including copper, copper alloy, aluminum, iron-nickel alloy, and Kovar™.

6. The method of claim 1 wherein the step of depositing includes the step of immersing the leadframe into a plating bath, the deposited layer adhering to the un-oxidized leadframe areas while not adhering to the oxidized areas.

7. The method of claim 6 wherein the step of depositing includes the step of flood plating.

8. The method of claim 6 further including the step of peeling away the deposited layer not adhering to the oxidized leadframe areas.

9. The method of claim 6 wherein the second metal includes a layer of nickel in contact with the first metal, a layer of palladium in contact with the nickel, and a layer of gold in contact with the palladium.

10. The method of claim 6 wherein the second metal includes tin.
